(19) United States
(12) Patent Application Publication
(10) Pub. No.: US 2025/0290361 A1
(43) Pub. Date: Sep. 18, 2025

(54) LID OPENING AND CLOSING STRUCTURE OF HOUSING

(71) Applicant: JVCKENWOOD CORPORATION, Yokohama-shi (JP)

(72) Inventor: Koji OKAWA, Yokohama-shi (JP)

(21) Appl. No.: 19/222,971

(22) Filed: May 29, 2025

Related U.S. Application Data
(63) Continuation of application No. PCT/JP2023/042643, filed on Nov. 29, 2023.

(30) Foreign Application Priority Data
Nov. 30, 2022 (JP) 2022-191938

(51) Int. Cl. E05D 7/10; E05D 1/04

(52) U.S. Cl. CPC E05D 7/1066; E05D 1/04

(57) ABSTRACT

A lid opening and closing structure of a housing includes the housing and a lid body. The housing includes an opening part and a shaft receiving hole part. The lid body includes: a lid part configured to be arranged to be changeable between a closed position covering the opening part and an open position exposing the opening part; and a hinge shaft part having elasticity and configured to be inserted into the shaft receiving hole part to be locked to the shaft receiving hole part. The hinge shaft part includes a root part, a free end part, and an intermediate part formed between the root part and the free end part.

### CROSS-REFERENCE TO RELATED APPLICATIONS

The present application is a continuation of International Application No. PCT/JP2023/042643 filed on Nov. 29, 2023, and based upon and claims the benefit of priority from Japanese Patent Application No. 2022-191938 filed on Nov. 30, 2022, the entire contents of which are incorporated herein by reference.

### BACKGROUND

The present invention relates to a lid opening and closing structure of a housing.

As described in Patent Literature 1 (JP 2005-51398 A), a lid opening and closing structure of a housing in an electronic device includes a terminal cover covering an opening part of the housing, and a tongue part extending from a main body of the terminal cover. A concave fitting part is formed at a tip part of the tongue part. The lid opening and closing structure of the housing is assembled by fitting the tip part of the tongue part to a concave part formed in the housing, and fitting the fitting part of the tip part of the tongue part to a tip of a mounting screw protruding in the concave part.

The lid opening and closing structure of the housing in the prior art is configured in such a manner that the tip part of the tongue part is fitted to the concave part formed in the housing, and the fitting part of the tip part of the tongue part is fitted to the tip of the mounting screw protruding in the concave part. Therefore, when the main body of the terminal cover is pinched with fingers to open the opening part of the housing, the terminal cover is easily detached from the housing.

### SUMMARY

The present embodiment provides a lid opening and closing structure of a housing, including: the housing that includes an opening part and a shaft receiving hole part; and a lid body that includes: a lid part configured to be arranged to be changeable between a closed position covering the opening part and an open position exposing the opening part; and a hinge shaft part having elasticity and configured to be inserted into the shaft receiving hole part to be locked to the shaft receiving hole part, wherein the hinge shaft part includes a root part, a free end part, and an intermediate part formed between the root part and the free end part.

### BRIEF DESCRIPTION OF DRAWINGS

FIG. 1 is a cross-sectional view illustrating a state where a lid part of a lid body is arranged in a closed position in a lid opening and closing structure of a housing according to the present embodiment.

FIG. 2 is a side view of the lid body used in the lid opening and closing structure of the housing according to the present embodiment.

FIG. 3 is a cross-sectional view illustrating a state where the lid part of the lid body e is arranged in an open position in the lid opening and closing structure of the housing according to the present embodiment.

FIG. 4A is a perspective view of a main part in the lid opening and closing structure of the housing according to the present embodiment, illustrating a state before a tip of a hinge shaft part of the lid body is inserted into a shaft receiving hole part of the housing.

FIG. 4B is a cross-sectional view of the main part in the lid opening and closing structure of the housing according to the present embodiment, illustrating a state before the tip of the hinge shaft part of the lid body is inserted into the shaft receiving hole part of the housing.

FIG. 4C is a cross-sectional view of the main part in the lid opening and closing structure of the housing according to the present embodiment, illustrating a state where the tip of the hinge shaft part of the lid body is inserted into the shaft receiving hole part of the housing, and then the tip of the hinge shaft part is pulled out inside the housing.

FIG. 5 is a cross-sectional view of the main part in the lid opening and closing structure of the housing according to the present embodiment, illustrating a positional relationship between the tip of the hinge shaft part of the lid body and a substrate when the tip of the hinge shaft part of the lid body is inserted into the shaft receiving hole part of the housing, and then the tip of the hinge shaft part is pulled out inside the housing.

### DETAILED DESCRIPTION

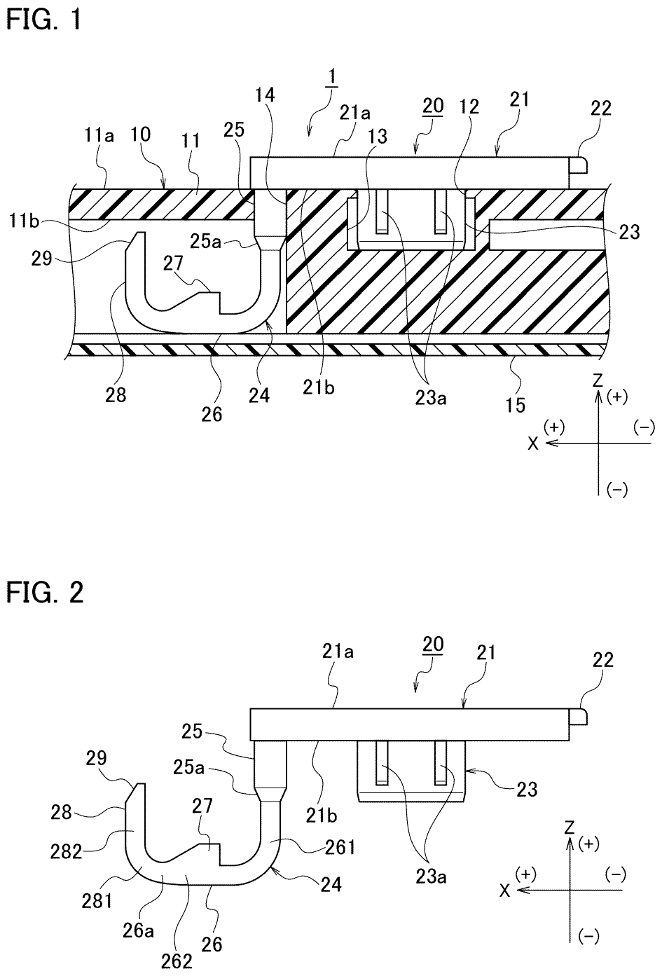

A lid opening and closing structure of a housing 1 according to the present embodiment will be described below with reference to FIGS. 1 to 5. As illustrated in FIGS. 1 to 5, the lid opening and closing structure of the housing 1 includes a housing 10 and a lid body (cover) 20.

An X direction illustrated in FIGS. 1 and 2 corresponds to a horizontal direction (longitudinal direction) of a lid part 21 of the lid body 20. A Z direction illustrated in FIGS. 1 and 2 corresponds to a vertical direction (thickness direction) of the lid part 21 of the lid body 20, and is orthogonal to the X direction. Both +X and −X sides illustrated in FIGS. 1 and 2 correspond to left and right sides of the lid part 21, respectively. Both +Z and −Z sides illustrated in FIGS. 1 and 2 correspond to upper and lower sides of the lid part 21, respectively.

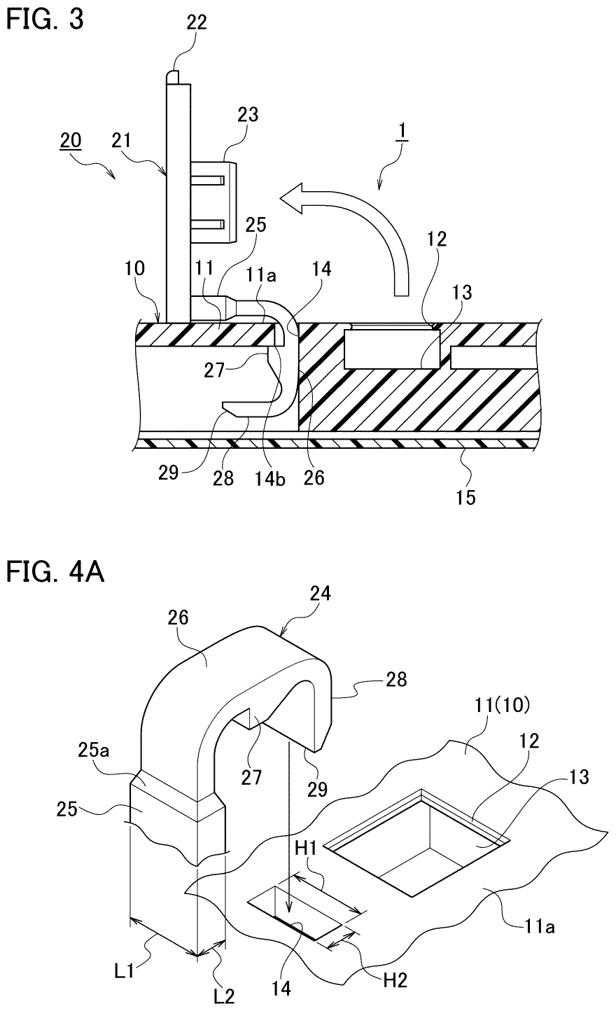

As illustrated in FIGS. 1 and 3, the housing 10 includes an opening part 12 and a shaft receiving hole part 14. The lid body 20 includes the lid part 21, which covers the opening part 12 of the housing 10, and a hinge shaft part 24 to be inserted in the shaft receiving hole part 14 and locked to the shaft receiving hole part 14. The lid part 21 can be arranged to be changeable between a closed position covering the opening part 12 of the housing 10 (see FIG. 1) and an open position exposing the opening part 12 of the housing 10 (see FIG. 3).

As illustrated in FIGS. 1, 3 and 4A, the housing 10 is a synthetic resin case. The opening part 12 is formed in a horizontal rectangular shape in a wall part 11 of the housing 10. The shaft receiving hole part 14 has a longitudinal width H1 equal to the longitudinal width of the opening part 12, and is formed in a rectangular shape in the wall part 11 of the housing 10. The opening part 12 corresponds to an upper surface opening part of a concave part 13 formed inside the housing 10. The concave part 13 houses an external connection terminal (not illustrated).

As illustrated in FIGS. 1 to 3, the lid body 20 is a cover made from silicone rubber (soft material). The lid part 21 and the hinge shaft part 24 are formed, as one body, from silicone rubber as a soft material, and each have elasticity (flexibility).

The lid part 21 includes a front surface 21a facing the outside of the housing 10, and a rear surface 21b facing the inside of the housing 10, when the lid body 20 is closed, that is, when the lid part 21 is arranged in the closed position. The lid part 21 is formed in the shape of a rectangular plate, and has a size to cover the opening part 12 and the shaft receiving hole part 14 of the housing 10. The lid part 21 has a knob piece 22 for opening and closing operation on a side surface on one end (−X side) of the lid part 21 near the front surface 21a side. The lid part 21 has a convex part 23 to be fitted to the concave part 13 of the housing 10, on a rear surface 21b at the center of the lid part 21. Ribs 23a and 23a for press-fitting are provided to protrude on both sides of the convex part 23, respectively.

As illustrated in FIG. 2, the hinge shaft part 24 is formed in an approximate U-shape and has a root part 25, an intermediate part 26, and a free end part 28. The root part 25 is fitted in the shaft receiving hole part 14 of the housing 10 when the lid body 20 is closed, that is, when the lid part 21 is arranged in the closed position. The root part 25 extends toward the lower (−Z side) of the lid part 21 from the rear surface 21b on the other end (+X side) of the lid part 21, which is positioned opposite to the one end (−X side) of the lid part 21. The intermediate part 26 extends from an end 25a (end part on the −Z side) of the root part 25 in a direction bent 90 degrees toward the left (+X side) of the lid part 21. Specifically, the intermediate part 26 has a curved part 261 bent 90 degrees toward the left (+X side) of the lid part 21 from the end 25a (end part on the −Z side) of the root part 25, and an extension part 262 connected to the curved part 261 and extending toward the left (+X side) of the lid part 21. The free end part 28 extends from the end 26a (end part on the +X side) of the intermediate part 26 in a direction bent 90 degrees toward the upper (+Z side) of the lid part 21. Specifically, the free end part 28 has a curved part 281 bent 90 degrees toward the upper (+Z side) of the lid part 21 from the end 26a (end part on the +X side) of the intermediate part 26, and an extension part 282 connected to the curved part 281 and extending toward the upper (+Z side) of the lid part 21. As described above, the hinge shaft part 24 is formed in such a manner that the root part 25, the intermediate part 26, and the free end part 28 form an approximate U-shape. Note that the angle at which the intermediate part 26 is bent from the end 25a of the root part 25, and the angle at which the free end part 28 is bent from the end 26a of the intermediate part 26 are not limited to 90 degrees. For example, the angle at which the intermediate part 26 is bent from the end 25a of the root part 25, and the angle at which the free end part 28 is bent from the end 26a of the intermediate part 26 may be approximately 90 degrees.

When expressed using the terms “horizontal direction” and “vertical direction” described above, the hinge shaft part 24 is formed by: the root part 25, which extends in the vertical direction from the rear surface 21b of the lid part 21 and is fitted to the shaft receiving hole part 14 of the housing 10 when the lid part 21 is arranged in the closed position; the intermediate part 26, which is bent in the horizontal direction from the root part 25; and the free end part 28, which is bent in the opposite direction (+Z side) to the direction where the root part 25 extends from the intermediate part 26. Therefore, the hinge shaft part 24 is formed to have an approximate U-shape in a side view by the root part 25, the intermediate part 26, and the free end part 28. Note that the direction where the root part 25 extends from the rear surface 21b of the lid part 21 need not be completely vertical, and may have a certain angle.

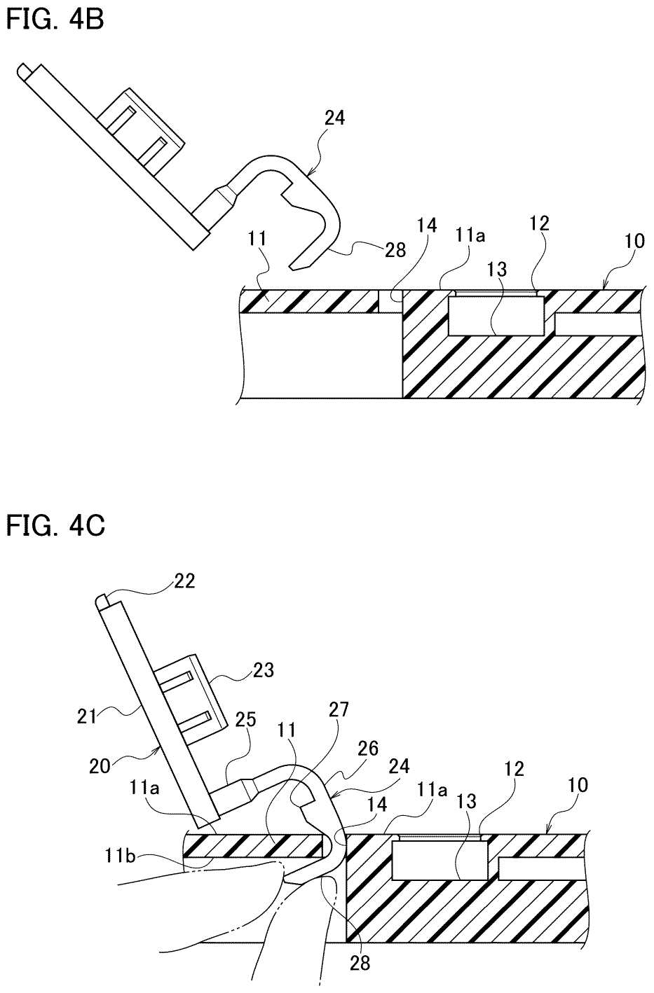

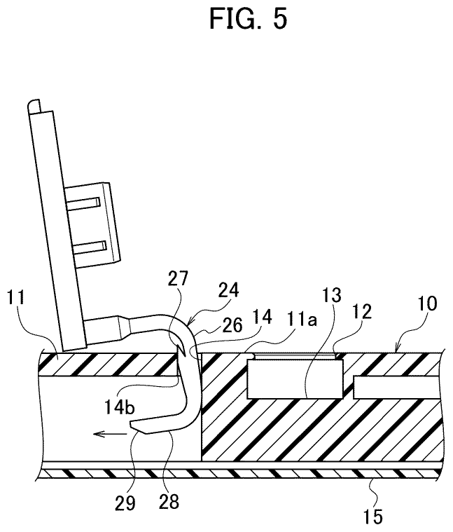

With this configuration, as illustrated in FIGS. 4A and 4C, after the free end part 28 of the hinge shaft part 24 is inserted into the shaft receiving hole part 14 from the front surface 11a of the wall part 11 of the housing 10, the free end part 28 can be grasped with fingers from a rear surface 11b of the wall part 11, and easily pulled out inside the housing 10. Here, as illustrated in FIG. 5, the tip side of the free end part 28 is configured to minimize interference with a structural object, such as the substrate 15, arranged in the housing 10. That is, since the hinge shaft part 24 is formed in an approximate U-shape, when the position of the lid part 21 of the lid body 20 is changed between the closed position and the open position, interference by the tip side of the free end part 28 with a structural object, such as the substrate 15, arranged in the housing 10 can be minimized. Note that it is desirable that the tip side of the free end part 28 does not interfere with a structural object, such as the substrate 15, arranged in the housing 10.

As illustrated in FIG. 4A, a longitudinal width L1 and a lateral width L2 of the root part 25 of the hinge shaft part 24 may be formed wider (thicker) than the longitudinal width H1 and a lateral width H2, respectively, of the shaft receiving hole part 14 of the housing 10, making the root part 25 thicker. Thus, when the lid body 20 is assembled in the housing 10, the root part 25 of the hinge shaft part 24 is press-fitted in the shaft receiving hole part 14 and fitted in the shaft receiving hole part 14.

On the upper side (+Z side) of the intermediate part 26 of the hinge shaft part 24, a locking projection 27 may be provided that is locked to the shaft receiving hole part 14 of the housing 10 when the lid part 21 is arranged in the open position. Specifically, the locking projection 27 is formed to project from the upper side (+Z side) of the intermediate part 26 toward the direction (+Z side), opposite to the direction (−Z side) where the root part 25 extends. Note that the locking projection 27 is also called a locking part.

As illustrated in FIG. 3, when the knob piece 22 of the lid part 21 of the lid body 20 is pinched to arrange the lid part 21 in the open position, upper and lower edges around the shaft receiving hole part 14 of the housing 10 are held between the root part 25 of the hinge shaft part 24 and the locking projection 27. Thus, the hinge shaft part 24 is locked to the shaft receiving hole part 14, and the lid part 21 is opened 90 degrees with respect to the opening part 12. That is, when the lid part 21 is arranged in the open position, the locking projection 27 is locked to an end edge 14b on the lower side (−Z side) of the shaft receiving hole part 14 of the housing 10. As described above, the hinge shaft part 24 functions as a hinge, and is configured in such a manner that interference by the tip side of the free end part 28 with a structural object, such as the substrate 15, arranged in the housing 10 is minimized when the position of the lid part 21 of the lid body 20 is changed between the closed position and the open position, and thus the lid part 21 can be stably held in the open position. When the lid part 21 is arranged in the open position, if the tip side of the free end part 28 does not interfere with a structural object, such as the substrate 15, arranged in the housing 10, a state can be stably held where the lid part 21 is opened approximately 90 degrees with respect to the opening part 12. Note that even if the lid body 20 includes only the intermediate part 26 without the locking projection 27 provided, a state where the lid part 21 is opened 90 degrees with respect to the opening part 12 can be held to some extent.

As illustrated in FIG. 2, the hinge shaft part 24 may have an inclined surface 29 on the tip side of the free end part 28. The inclined surface 29 of the free end part 28 can minimize the interference by the tip side of the free end part 28 with a structure, such as the substrate 15, arranged in the housing 10, when the lid part 21 is arranged in the closed position as illustrated in FIG. 5.

Next, with reference to FIGS. 4A to 4C, and FIG. 5, a procedure for assembling the lid body 20 in the housing 10 will be described.

As illustrated in FIGS. 4A and 4B, the tip of the free end part 28 of the hinge shaft part 24 is inserted into the shaft receiving hole part 14 from the front surface 11a of the wall part 11 of the housing 10.

As illustrated in FIG. 4C, the tip of the free end part 28 is exposed to the rear surface 11b of the wall part 11 of the housing 10 by inserting the tip of the free end part 28 of the hinge shaft part 24 into the shaft receiving hole part 14.

As illustrated in FIGS. 4C and 5, the tip of the free end part 28 of the hinge shaft part 24 is grasped with fingers and pulled out inside the housing 10. Note that the tip of the free end part 28 may be pushed into the shaft receiving hole part 14 from the front surface 11a of the wall part 11 of the housing 10. Thus, as illustrated in FIG. 1, the root part 25 of the hinge shaft part 24 can be press-fitted into the shaft receiving hole part 14 of the housing 10 and fitted in the shaft receiving hole part 14, and thus the lid body 20 can be assembled in the housing 10.

As described above, in the lid opening and closing structure of the housing 1, the lid body 20 can be easily and reliably assembled in the housing 10 by simply inserting the free end part 28 of the hinge shaft part 24 of the lid body 20 in the shaft receiving hole part 14 from the front surface 11a of the wall part 11 of the housing 10, and pulling it out to the rear surface 11b of the wall part 11.

In addition, the hinge shaft part 24 of the lid body 20 is formed in an approximate U-shape by the root part 25, the intermediate part 26, and the free end part 28, and the inclined surface 29 is formed on the tip side of the free end part 28. Thus, when the lid opening and closing structure of the housing 1 is assembled, interference by the hinge shaft part 24 with a structural object, such as the substrate 15, in the housing 10 can be minimized.

Furthermore, as illustrated in FIG. 3, when the lid part 21 of the lid body 20 is arranged in the open position, the locking projection 27 of the hinge shaft part 24 is locked to the end edge 14b of the shaft receiving hole part 14 of the housing 10 on the lower side (−Z side), and thus the hinge shaft part 24 of the lid body 20 can be prevented from coming out of the shaft receiving hole part 14. Thus, when the lid body 20 is opened, the lid body 20 can be reliably prevented from coming out of the housing 10. In addition, since the lid part 21 of the lid body 20 can be stably held in a state of being opened to approximately 90 degrees with respect to the opening part 12 of the housing 10, it is possible to perform connection to an external connection terminal with one hand after opening the lid body 20, which facilitates work.

The present embodiment is not limited to the configuration described above, and various modifications can be made without departing from the gist of the present invention. The lid body is made from silicone rubber (soft material), but the lid body may be made from soft resin, for example.

What is claimed is:

1. A lid opening and closing structure of a housing, comprising:
the housing that includes an opening part and a shaft receiving hole part; and
a lid body that includes: a lid part configured to be arranged to be changeable between a closed position covering the opening part and an open position exposing the opening part; and a hinge shaft part having elasticity and configured to be inserted in the shaft receiving hole part to be locked to the shaft receiving hole part, wherein
the lid part includes a front surface facing outside of the housing, and a rear surface facing inside of the housing when arranged in the closed position,
the hinge shaft part is formed in an approximate U-shape by: a root part that extends in a vertical direction from the rear surface of the lid part, and is configured to be fitted in the shaft receiving hole part of the housing when the lid part is arranged in the closed position; an intermediate part that is bent in a horizontal direction from the root part; and a free end part that is bent in a direction opposite to a direction where the root part extends from the intermediate part,
the intermediate part includes a locking part formed in a direction opposite to the direction where the root part extends, and
the lid part is configured to be locked, when arranged in the open position, in a state where the lid part is opened 90 degrees with respect to the shaft receiving hole part, by holding upper and lower edges of the shaft receiving hole part of the housing between the root part and the locking part.

2. The lid opening and closing structure of the housing according to claim 1, wherein
a length in the intermediate part from a free end part side of the locking part to a tip of the free end part is such that when the hinge shaft part is passed through the shaft receiving hole part of the housing from outside of the housing toward inside of the housing, the free end part can be pulled out from the inside of the housing by grasping with fingers.

3. The lid opening and closing structure of the housing according to claim 1, wherein
the hinge shaft part includes an inclined surface on a tip side of the free end part.

4. The lid opening and closing structure of the housing according to claim 1, wherein
the lid part and the hinge shaft part are formed from a soft material as one body, and
the root part of the hinge shaft part is formed thicker than a width of the shaft receiving hole part, and is configured to be press-fitted in the shaft receiving hole part when the lid part is assembled in the housing.
